(19) United States
(12) Patent Application Publication
(10) Pub. No.: US 2026/0177505 A1
(43) Pub. Date: Jun. 25, 2026

(54) CONTAMINATED OPTICS DETECTION FOR A THERMAL IMAGER

(71) Applicant: Seek Thermal, Inc., Goleta, CA (US)

(72) Inventors: Matt Buckley, Santa Barbara, CA (US); Brian Nehring, Santa Barbara, CA (US); William J. Parrish, Santa Barbara, CA (US)

(21) Appl. No.: 19/430,063

(22) Filed: Dec. 22, 2025

Related U.S. Application Data
(60) Provisional application No. 63/738,317, filed on Dec. 23, 2024.

(51) Int. Cl. G01N 21/94; G01N 21/15; H10F 39/00

(52) U.S. Cl. CPC G01N 21/94; G01N 2021/157; H10F 39/8063

(57) ABSTRACT

Devices and methods for an approach to determine if the optics arrangement of a thermal imager has been contaminated during use in a dirty environment. Elements of such a thermal imager include a radiation emitter, a radiation detector, optics and a controller executing control and user interface processes. The emitter is a device that emits energy in the infrared spectrum that would normally pass through the optics of the system when clean. The emitter may be placed in such a way, in the system, that the energy it emits usually is transmitted through the optics but can be reflected off the optical surface and back to the detector. As the contamination level of the optical surface changes, the reflectivity of the optical surface changes and the change in the amount of energy reflected back to the detector may be processed and acted upon.

### CROSS-REFERENCE TO RELATED APPLICATIONS

This application claims the benefit of U.S. Provisional Application Ser. No. 63/738,317, filed Dec. 23, 2024, titled CONTAMINATED OPTICS DETECTION FOR A THERMAL IMAGER, which is incorporated by reference herein in its entirety.

### FIELD

The present disclosure generally relates to imaging systems including thermal imaging sensors, and in particular to devices and methods for detecting optics contamination and alerting users that optics need cleaning

### BACKGROUND

Thermal imagers are used in challenging environments, such as firefighting applications, due to their ability to see through airborne smoke, ash, steam and darkness better than a human's eyes. However, in such dirty environments, contamination can accumulate on the optics of a thermal imager and cause a reduction in performance due to reduced ability of light to pass through the optics.

### SUMMARY

The systems of this disclosure each have several innovative aspects, no single one of which is solely responsible for its desirable attributes. Without limiting the scope as expressed by the claims that follow, its more prominent features will now be discussed briefly.

The current disclosure provides devices and methods for an approach to determine if the optics arrangement of a thermal imager has been contaminated during use in a dirty environment. Elements of such a thermal imager may include a radiation emitter, a radiation detector, optics, and a controller executing control and/or user interface processes. The emitter can be a device that emits energy in the infrared spectrum that would normally pass through the optics of the system when clean. The emitter may be placed in such a way, in the system, that the energy it emits usually is transmitted through the optics but can be reflected off the optical surface and back to the detector. As the contamination level of the optical surface changes, the reflectivity of the optical surface changes and the change in the amount of energy reflected back to the detector may be processed and acted upon.

In a first aspect, a thermal imager includes a controller executing one or more imaging processes and one or more user interface processes; an imaging sensor; an optics arrangement comprising at least one external optical element disposed between the imaging sensor and an external environment; at least one radiation emitter disposed in a region within optical view of the external optical element on a same side of the optics arrangement as the imaging sensor, wherein the radiation emitter produces radiation within a transmission band of the optics arrangement; and a radiation detection element configured to detect reflected radiation from the radiation emitter reflected by the optics arrangement; wherein the reflected radiation is indicative of contamination affecting the transmission of the optics arrangement.

In some embodiments, the imaging sensor is a focal plane array (FPA).

In some embodiments, the emitter comprises one or more of a light emitting diode (LED), a resistor, a heater, a laser diode, or other radiation source whose emitted radiation will pass through the optics arrangement when the optics arrangement is not contaminated.

In some embodiments, the detector comprises one or more of an infrared focal plane array, a photodetector, a pyrometer, or any detector sensitive to the radiation emitted by the emitter.

In some embodiments, he detector is a separate device from the imaging sensor.

In some embodiments, the detector is the imaging sensor, and the imaging sensor is an FPA.

In some embodiments, the emitted radiation is modulated to at least one of increase the detection of any reflected radiation or aid in removal of the emitter signal from imaging data.

In some embodiments, the external optical element is an element including one or more of a lens, a window, or a filter.

In some embodiments, the controller generates a user alert in response to detecting a level of detection of reflected emitter radiation exceeding a predetermined threshold.

In some embodiments, the thermal imager is a firefighting tool and the user alert is a visual or audible indication that the imager external optics needs cleaning.

In a second aspect, a method of operating a thermal imager is disclosed. The thermal imager includes a controller, an imaging sensor, an optics arrangement comprising at least one external optical element disposed between the imaging sensor and an external environment, at least one radiation emitter disposed in a region within optical view of the external optical element on a same side of the optics arrangement as the imaging sensor, and a radiation detector element configured to detect reflected radiation from the radiation emitter reflected by the optics arrangement. The method includes activating the emitter to emit radiation within a transmission band of the optics arrangement; directing the emitted radiation toward the optics arrangement; detecting any radiation from the emitter reflected by the optics arrangement; and determining that the external optical element is contaminated based on detection, by the controller, that the detected radiation exceeds a predetermined threshold.

In some embodiments, the imaging sensor is a focal plane array.

In some embodiments, the emitter comprises one or more of an LED, a resistor, a heater, a laser diode or other radiation source whose emitted radiation will pass through the optics arrangement when the optics arrangement is not contaminated.

In some embodiments, the detector comprises one or more of an infrared focal plane array, a photodetector, a pyrometer or any detector sensitive to the radiation emitted by the emitter.

In some embodiments, the detector is a separate device from the imaging sensor.

In some embodiments, the detector is the imaging sensor, and the imaging sensor is an FPA.

In some embodiments, the method further includes modulating the emitted radiation to at least one of increase the detection of any reflected radiation or to aid in removal of the emitter signal from imaging data.

In some embodiments, the external optical element is an element including one or more of a lens, a window or a filter.

In some embodiments, the method further includes generating, by the controller, a user alert in response to determining that the external optical element is contaminated.

In some embodiments, the thermal imager is a firefighting tool and the user alert is a visual or audible indication that the imager external optics needs cleaning.

### BRIEF DESCRIPTION OF THE DRAWINGS

The above-mentioned aspects, as well as other features, aspects, and advantages of the present technology will now be described in connection with various implementations, with reference to the accompanying drawings. The illustrated implementations are merely examples and are not intended to be limiting. Throughout the drawings, similar symbols typically identify similar components, unless context dictates otherwise.

FIG. 1 shows exemplary aspects of an example thermal imager.

FIG. 2 shows operation of the imager with a separate radiation detector.

FIG. 3 shows operation of the imager with the imager sensor, such as a focal plane array (FPA) used as the radiation detector.

FIG. 4 is flow chart of an illustrative method of operation.

### DETAILED DESCRIPTION

The following description is directed to certain implementations for the purpose of describing the innovative aspects of this disclosure. However, a person having ordinary skill in the art will readily recognize that the teachings herein can be applied in a multitude of different ways.

Generally described, embodiments of the present disclosure relate to applying thermal imaging to applications in environments where the external optics of a thermal imager may become contaminated. A particularly important application for such imagers is firefighting, although it is to be understood that the teachings of the current disclosure apply to other dirty environment applications as well, where the optics may come into contact with any sort of particulate matter such as dust, dirt, ash, smoke, liquid particles, or the like. Firefighting, however, is particularly useful to illustrate the benefits derived from this disclosure.

Thermal imagers are used in firefighting applications, as stated above due to their ability to see through many atmospheric obscuring conditions, such airborne smoke, ash, steam and darkness. In many such environments a thermal image is superior to a human's eyes. However, in such very dirty environments, contamination can accumulate on the external optics of a thermal imager and cause a reduction in performance and the ability to see.

Currently, the typical solution for addressing these contaminated optics is for a user such as a firefighter to use their gloved hand to wipe the optics to remove the contamination. Firefighters are typically trained to look for the signs of accumulating contamination, or they are trained to periodically wipe the optics in fixed intervals of time under the assumption that contamination is always accumulating. The problem with these scenarios is that in this extremely high stress environment, firefighters may become distracted or forget to wipe the optics, leading to diminished imager performance that can result in dangerous situations for the firefighter. The present disclosure is intended to remove the burden of interpreting, deciding, or remembering to clean the optics from the firefighter by detecting dirty optics and alerting the firefighter that cleaning is recommended. Furthermore, this system has benefits over a simple timer-based system where the user is told to clean the window periodically, as it will be less likely to create a situation where the user begins to ignore a repeated cleaning procedure over time.

The dirty optics detection system may include an emitter and a detector. The emitter produces a signal that will transmit through clean optics and will reflect off of dirty optics. When the signal reflects off of dirty optics, the signal will return to the detector where it can be identified by software and an alert can be displayed to the firefighter.

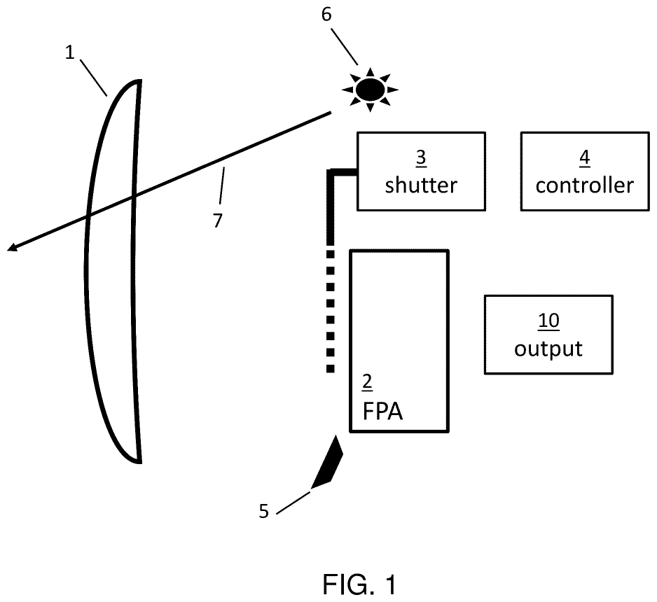

Referring to FIG. 1, elements of an example system are shown. The system can include an imaging sensor, such as a focal plane array (FPA) 2. It also can include an optics arrangement 1, a shutter 3, and a controller 4 executing control and user interface processes. It can also include an emitter 6 and a detector 5. In some embodiments, the system may include more or fewer elements than those shown in FIG. 1. For example, some embodiments of a thermal imaging system may not include a shutter 3.

The emitter 6 is a device that emits energy 7, which may be in the thermal spectrum, or any spectral band to which the optics arrangement 1 would normally be transparent when the optics are clean. The emitter 6 may be an LED, a resistor, a heater, a laser diode or a similar device, or any other device capable of emitting electromagnetic radiation. The emitter is placed in such a way, in the system, that the energy it emits can be reflected off the optical surface and back to the detector 5. For example, the detector 5 and the emitter 6 may be disposed on the same side of the optics arrangement 1 as the FPA 2. In some embodiments, the detector 5 may be located at a location where it is capable of receiving radiation from the emitter 6 when reflected off of a contaminated optics arrangement 1, but where it will not ordinarily receive light from outside the system entering via the optics arrangement 1.

If some or all radiation from the emitter 6 is reflected off of surfaces of the optics arrangement 1, the detector 5 detects the reflected radiation. If not contaminated, the optics arrangement 1 should be transparent and should reflect little to no radiation from the emitter 6. The detector 5 may be any suitable detector such as an infrared focal plane array, a photodetector, a pyrometer, or a similar device. The optics arrangement 1 can have an external surface that is the part of the system that is exposed to the outside environment and that is subject to contamination. This may be a lens, a window, a filter, or other suitable exterior optical element.

The system may further include an output 10 for providing alerts or other information to a user of the imaging system. In some embodiments the output can include a display device and/or an audio device such that the system can provide visual and/or audio alerts to the user. For example, if the controller 4 determines that enough contamination has accumulated on the optics arrangement 1 that cleaning is needed, a display device of the output may display a symbolic or text message directing the user to clean the optics arrangement 1. Additionally or alternatively, an audio device of the output 10 may play an audible message instructing the user to clean the optics arrangement 1 and/or may output an alert sound accompanying a symbolic or text message display on a display device of the output 10.

In some embodiments, any or all of the components described herein can be located at least partially within a housing to protect the components from damage from outside objects, conditions, or substances. In one example, the FPA 2, the shutter 3, the controller 4, the emitter 6, and the detector 5 may all be contained within a housing. The output 10 may be located within the housing as well, or a portion of the output 10 such as a display device may form a portion of the exterior of the housing. Similarly, the outer surface of the optics arrangement 1 may form a portion of the exterior of the housing.

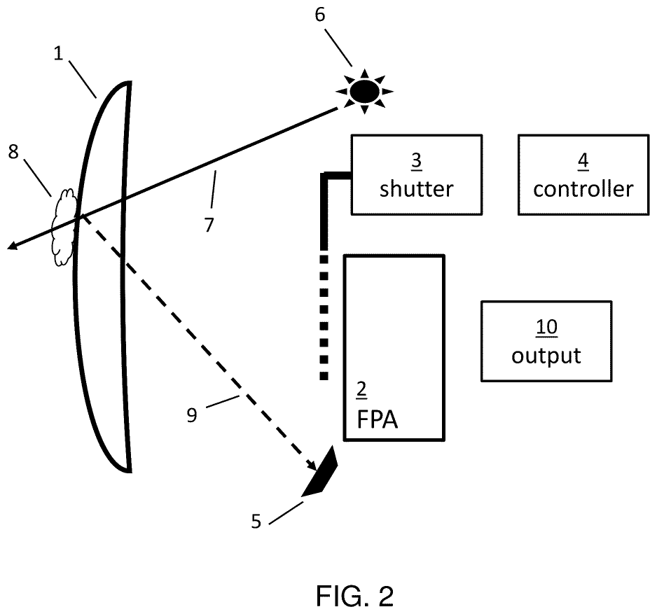

As shown in FIG. 2, as the contamination level of the optical surface changes, the reflectivity of the optical surface changes correspondingly. As contamination 8 accumulates on the surface of the optics arrangement 1, the change in the amount of energy 9 reflected back to the detector 5 can be detected at the detector 5. The amount of reflected energy 9 detected at the detector 5 can be processed and acted upon by the controller 4.

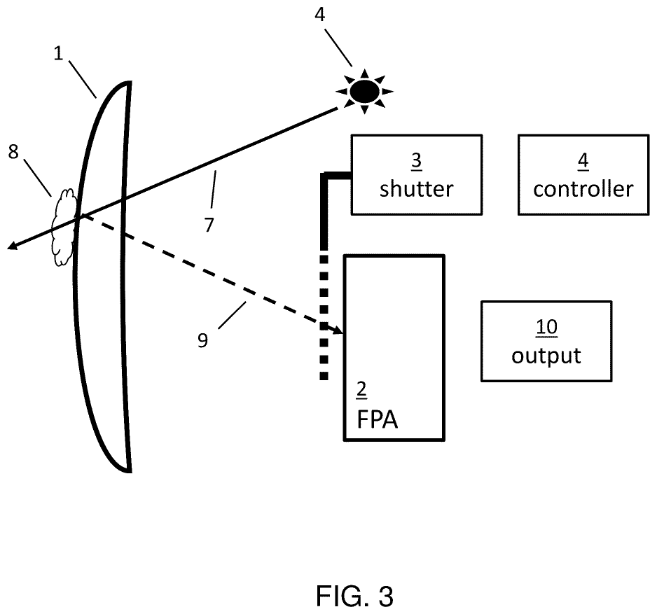

As shown in FIG. 3, the FPA 2 itself can be used as the detector, rather than including a separate detector 5 as shown in FIG. 2, depending on the spectrum of the radiation produced by the emitter

The controller 4 and one or more processes executed thereon can be responsible for identifying a change in the reflection resulting from a change in contamination of the optics. The reflection may be represented as a discrete energy source in a corner or edge of the detector's field of view, or it may be represented as a diffuse out-of-focus energy level affecting the entire field of view. The emitter may be modulated at a frequency that the controller can use to isolate and remove emitter signal from the image such that the emitter does not cause imaging artifacts visible by the user. When the controller determines that contamination has crossed above a certain threshold, it can indicate to the user that a cleaning procedure should be performed. As well as alerts given to the user, such as a reminder to clean the optics, for more complex systems, an actual cleaning action, such as a spray wash and/or a wiper action may be triggered automatically or manually using a spray and/or wiper device in communication with the controller 4.

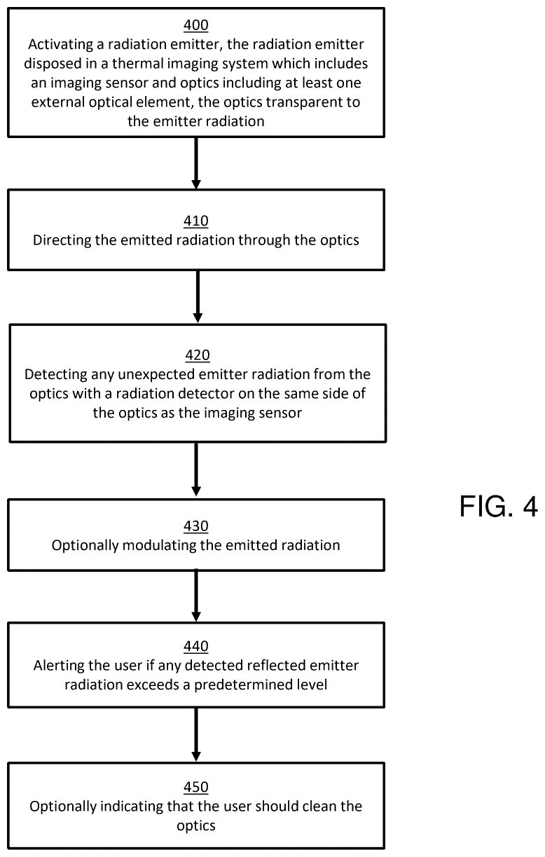

FIG. 4 illustrates an example method for operating a thermal imager with contaminated optics detection. The method of FIG. 4 may be implemented using the systems illustrated in FIGS. 1-3 and/or may be implemented using any other suitable system capable of performing the operations described herein.

In step 400, the radiation emitter is activated. This may be continuous or at selected times depending on the specific approach used for contamination detection. The emitter radiation can be in a band to which the imager optics (e.g., optics arrangement 1 of FIGS. 1-3) is normally transparent. The spectral band may or may not be within the imager operating bands, as long as it can pass through the optics when the optics are clean. In some embodiments, the radiation emitter may be activated repetitively at a known frequency or otherwise modulated to produce a time-varying signal that can be detected while other radiation from outside the system is entering via the optics.

In step 410, the emitted radiation is directed though the optics as determined by the placement and beam steering characteristics of the emitter.

In step 420, any radiation reflected by the optics is detected by a detector (e.g., detector 5 of FIGS. 1-3). The detector may be a separate device (e.g., detector 5 of FIGS. 1-3), or for suitable arrangements and spectral bands could actually be the FPA itself (e.g., FPA 2 of FIGS. 1-3).

In step 430, optionally the emitted radiation can be modulated by the emitter or any suitable optical modulating mechanism in the optical path to increase the detection sensitivity and/or to remove the detected radiation from the image data for the case where the FPA is the detector.

In step 440, if the detector detects a level of reflected energy above a predetermined threshold level, the controller (e.g., controller 4 of FIGS. 1-3) can provide an alert to a user that the optics arrangement is contaminated. For example, the controller 4 of FIGS. 1-3 can cause a display or audio device of the output 10 to provide a visual and/or audio alert as discussed above.

In step 450, the alert may take the form of a direct instruction to clean the optics. Alternatively, the alert may be an indication that the optics arrangement is contaminated or a corresponding symbol. It is also possible depending on the system configuration that detected contamination trigger an active system response such as spray or wiper action for example

It should be understood, that the above teaching could apply equally to looking for attenuation as opposed to reflection, if the emitter is placed outside the external optics. But for a rugged imager such as a firefighting tool, it may be advantageous to add components to the interior of the imager.

Depending on the embodiment, certain acts, events, or functions of any of the processes described herein can be performed in a different sequence, can be added, merged, or left out altogether (e.g., not all described acts or events are necessary for the practice of the algorithm). Moreover, in certain embodiments, acts or events can be performed concurrently, e.g., through multi-threaded processing, interrupt processing, or multiple processors or processor cores or on other parallel architectures, rather than sequentially.

The various illustrative logical blocks, modules, and process steps described in connection with the embodiments disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described in connection with the embodiments disclosed herein can be implemented or performed by a machine, such as a processor configured with specific instructions, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. For example, the LUT described herein may be implemented using a discrete memory chip, a portion of memory in a microprocessor, flash, EPROM, or other types of memory.

The elements of a method, process, or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of computer-readable storage medium known in the art. An exemplary storage medium can be coupled to the processor such that the processor can read information from, and write information to, the storage medium. In the alternative, the storage medium can be integral to the processor. The processor and the storage medium can reside in an ASIC. A software module can comprise computer-executable instructions which cause a hardware processor to execute the computer-executable instructions.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements, and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment. The terms “comprising,” “including,” “having,” “involving,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, and Z,” unless specifically stated otherwise, is otherwise understood with the context as used in general to present that an item, term, etc., may be either X, Y or Z, or any combination thereof (e.g., X, Y and/or Z). Thus, such disjunctive language is not generally intended to, and should not, imply that certain embodiments require at least one of X, at least one of Y or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to illustrative embodiments, it will be understood that various omissions, substitutions, and changes in the form and details of the devices or processes illustrated can be made without departing from the spirit of the disclosure. As will be recognized, certain embodiments described herein can be embodied within a form that does not provide all of the features and benefits set forth herein, as some features can be used or practiced separately from others. All changes which come within the meaning and range of equivalency of the claims are to be embraced within their scope.

What is claimed is:

1. A thermal imager comprising;
a controller executing one or more imaging processes and one or more user interface processes;
an imaging sensor;
an optics arrangement comprising at least one external optical element disposed between the imaging sensor and an external environment;
at least one radiation emitter disposed in a region within optical view of the external optical element on a same side of the optics arrangement as the imaging sensor, wherein the radiation emitter produces radiation within a transmission band of the optics arrangement; and
a radiation detection element configured to detect reflected radiation from the radiation emitter reflected by the optics arrangement;
wherein the reflected radiation is indicative of contamination affecting the transmission of the optics arrangement.

2. The thermal imager of claim 1, wherein the imaging sensor is a focal plane array (FPA).

3. The thermal imager of claim 1, wherein the emitter comprises one or more of a light emitting diode (LED), a resistor, a heater, a laser diode, or other radiation source whose emitted radiation will pass through the optics arrangement when the optics arrangement is not contaminated.

4. The thermal imager of claim 1, wherein the detector comprises one or more of an infrared focal plane array, a photodetector, a pyrometer, or any detector sensitive to the radiation emitted by the emitter.

5. The thermal imager of claim 4, wherein the detector is a separate device from the imaging sensor.

6. The thermal imager of claim 4, wherein the detector is the imaging sensor, and the imaging sensor is an FPA.

7. The thermal imager of claim 1, wherein emitted radiation is modulated to at least one of increase the detection of any reflected radiation or aid in removal of the emitter signal from imaging data.

8. The thermal imager of claim 1, wherein the external optical element is an element including one or more of a lens, a window, or a filter.

9. The thermal imager of claim 1, wherein the controller generates a user alert in response to detecting a level of detection of reflected emitter radiation exceeding a predetermined threshold.

10. The thermal imager of claim 9, wherein the thermal imager is a firefighting tool and the user alert is a visual or audible indication that the imager external optics needs cleaning.

11. A method of operating a thermal imager, the thermal imager comprising a controller, an imaging sensor, an optics arrangement comprising at least one external optical element disposed between the imaging sensor and an external environment, at least one radiation emitter disposed in a region within optical view of the external optical element on a same side of the optics arrangement as the imaging sensor, and a radiation detector element configured to detect reflected radiation from the radiation emitter reflected by the optics arrangement, the method comprising:
activating the emitter to emit radiation within a transmission band of the optics arrangement;
directing the emitted radiation toward the optics arrangement;
detecting any radiation from the emitter reflected by the optics arrangement; and
determining that the external optical element is contaminated based on detection, by the controller, that the detected radiation exceeds a predetermined threshold.

12. The method of claim 11, wherein the imaging sensor is a focal plane array.

13. The method of claim 11, wherein the emitter comprises one or more of an LED, a resistor, a heater, a laser diode or other radiation source whose emitted radiation will pass through the optics arrangement when the optics arrangement is not contaminated.

14. The method of claim 11, wherein the detector comprises one or more of an infrared focal plane array, a photodetector, a pyrometer or any detector sensitive to the radiation emitted by the emitter.

15. The method of claim 14, wherein the detector is a separate device from the imaging sensor.

16. The method of claim 14, wherein the detector is the imaging sensor, and the imaging sensor is an FPA.

17. The method of claim 11, further comprising modulating the emitted radiation to at least one of increase the detection of any reflected radiation or to aid in removal of the emitter signal from imaging data.

18. The method of claim 11, wherein the external optical element is an element including one or more of a lens, a window or a filter.

19. The method of claim 11, further comprising generating, by the controller, a user alert in response to determining that the external optical element is contaminated.

20. The method of claim 19, wherein the thermal imager is a firefighting tool and the user alert is a visual or audible indication that the imager external optics needs cleaning.
